(19) United States
(12) Patent Application Publication
(10) Pub. No.: US 2020/0395732 A1
(43) Pub. Date: Dec. 17, 2020

(54) Integrated Diode Laser Coolers

(71) Applicant: Trumpf Photonics, Inc., Cranbury, NJ (US)

(72) Inventors: Stefan Heinemann, Hightstown, NJ (US); Le Zhao, Bethlehem, PA (US)

(21) Appl. No.: 16/441,926

(22) Filed: Jun. 14, 2019

(51) Int. Cl. H01S 5/024; H01S 5/022

(52) U.S. Cl. CPC H01S 5/02476; H01S 5/0224; H01S 5/02415

(57) ABSTRACT

A laser diode device includes: a heat sink including a main body portion and an electrical insulating layer on the main body portion; a mounting layer on the electrical insulating layer, in which the mounting layer includes a first mounting pad and a second mounting pad electrically isolated from one another; a laser diode bar on the first mounting pad; a contact bar on the second mounting pad; a first solder layer providing an electrical connection between the contact bar and the second mounting pad; and multiple wire bonds providing an electrical connection from a top surface of the laser diode bar to a top surface of the contact bar.

### TECHNICAL FIELD

The present disclosure relates to integrated diode laser coolers.

### BACKGROUND

High-powered semiconductor laser diodes are cooled to keep the junction temperature and carrier leakage low and reliability high. Laser diodes can be mounted to electrically insulated coolers, which helps reduce thermal impedance.

### SUMMARY

In general, in some aspects, the subject matter of the present disclosure may be embodied in laser diode devices that include: a heat sink including a main body portion and an electrical insulating layer on the main body portion; a mounting layer on the electrical insulating layer, in which the mounting layer includes a first mounting pad and a second mounting pad electrically isolated from one another; a laser diode bar on the first mounting pad; a contact bar on the second mounting pad; a first solder layer providing an electrical connection between the contact bar and the second mounting pad; and multiple wire bonds providing an electrical connection from a top surface of the laser diode bar to a top surface of the contact bar.

Implementations of the laser diode devices may include one or more of the following features. For example, in some implementations, the first mounting pad is separated from the second mounting pad by a gap. A width of the gap between facing edges of the first mounting pad and the second mounting pad may be less than about 1.5 mm. An edge of the contact bar may extend over an edge of the second mounting pad and overlap the gap. The edge of the contact bar may extend over the edge of the second mounting pad by less than about 0.5 mm. An edge of the contact bar may extend entirely over the gap. An edge of the contact bar may extend over the gap and over a portion of the first mounting pad. A dielectric material may fill the gap. The dielectric material may include an epoxy. A distance between facing edges of the contact bar and the laser diode bar may be between approximately 0.5 mm to approximately 1 mm. The laser diode device may include a second solder layer between the first mounting pad and a bottom surface of the laser diode bar, in which the second solder layer provides an electrical connection between a first electrode on the bottom surface of the laser diode bar and the first mounting pad. The top surface of the laser diode bar may include a second electrode, and the multiple wire bonds may provide an electrical connection from the second electrode to the contact bar. Each wire bond of the multiple wire bonds may have a length of between approximately 5 mm and approximately 6 mm.

In general, in some aspects, the subject matter of the present disclosure may be embodied in methods of manufacturing a laser diode device, in which the methods include: providing a heat sink, in which the heat sink includes a main body portion, an electrical insulating layer on the main body portion, and a mounting layer on the electrical insulating layer; modifying the mounting layer to form a first mounting pad and a second mounting pad electrically isolated from the first mounting pad; mounting a laser diode bar on the first mounting pad so that the laser diode is electrically connected to the first mounting pad; mounting a contact bar on the second mounting pad; electrically connecting the laser diode bar to the contact bar by providing multiple wire bonds that couple to a top surface of the laser diode bar and to a top surface of the contact bar.

Implementations of the methods may include one or more of the following features. For example, in some implementations, modifying the mounting layer to form the first mounting pad and the second mounting pad includes stamping the mounting layer to form a gap within the mounting layer in which the gap defines a separation between the first mounting pad and the second mounting pad.

Modifying the mounting layer to form the first mounting pad and the second mounting pad may include milling or etching the mounting layer to form a gap within the mounting layer in which the gap defines a separation between the first mounting pad and the second mounting pad. In some implementations, modifying the mounting layer to form the first mounting pad and the second mounting pad includes using stamping, milling or etching to form a shelf or ledge on the first and/or second mounting pad.

In some implementations, modifying the mounting layer to form the first mounting pad and the second mounting pad includes forming a gap within the mounting layer, in which the gap defines a separation between the first mounting pad and the second mounting pad, and in which mounting the contact bar includes positioning the contact bar on the second mounting pad such that an edge of the contact bar extends over the gap. The method may further include filling the gap with a dielectric material.

In some implementations, mounting the contact bar on the second mounting pad includes soldering the contact bar to the second mounting pad to electrically connect the contact bar to the second mounting pad.

In some implementations, the methods include soldering the contact bar to the second mounting pad and soldering the laser diode bar to the first mounting pad at the same time.

Implementations of the subject matter disclosed herein may include one or more of the following advantages. For example, in some implementations, electrically isolating the mounting pads from one another may eliminate the need to use an adhesive plastic foil for bonding an electrical contact bar. Eliminating the foil can also prevent contamination that may otherwise be caused by the foil during the packaging process. In some implementations, the devices and methods disclosed herein allow the number of packaging steps to be reduced offering increased time savings and potentially allowing for automation of the packaging process.

The details of one or more embodiments of the invention are set forth in the accompanying drawings and the description below. Other features and advantages of the invention will be apparent from the description and drawings, and from the claims.

### BRIEF DESCRIPTION OF THE DRAWINGS

FIG. 1A is a schematic that illustrates a top view of an example of an electrically insulated laser diode cooler with multiple mounting pads.

FIG. 1B is a schematic that illustrates a side view through section A-A of the electrically insulated laser diode cooler of FIG. 1A.

FIG. 2A is a schematic that illustrates a top view of an example of a semiconductor laser diode and electrical contact mounted to an electrically insulated laser diode cooler with multiple mounting pads.

FIG. 2B is a schematic that illustrates a side view through section A-A of the electrically insulated laser diode cooler of FIG. 2A.

FIG. 2C is a schematic that illustrates a side view through section B-B of the electrically insulated laser diode cooler of FIG. 2A.

FIG. 3 is a schematic that illustrates a bottom view of an example of a contact bar.

### DETAILED DESCRIPTION

To keep junction temperature, carrier leakage low and reliability high, high-powered semiconductor laser diodes may be cooled by mounting the laser diodes to electrically insulated coolers. An example electrically insulated cooler to which laser diodes can be mounted is the ILASCO diode cooler, which is fabricated from a stack of thin copper sheets sandwiched between two ceramic-copper sheets, having high thermal conductivity. The individual stacked copper sheets included an etched structure defining a coolant passage through which a coolant is provided. An electrically conductive mounting pad is formed on a top surface of one of the ceramic sheets. The laser diode then may be mounted directly to the electrically conductive mounting pad using a solder. For example, the p-side contact of the semiconductor laser diode may be mounted directly to the electrically conductive mounting pad. Similarly, a separate contact bar may be mounted to the electrically conductive mounting pad. The separate contact bar may be used to provide an electrically conductive platform to which the opposite contact (e.g., the n-side contact) of the laser diode may be coupled. To prevent the contact bar from electrically shorting through the mounting pad to the p-side contact, the contact bar is mounted to the electrically conductive mounting pad using an insulating adhesive, such as a plastic foil. Parts of the plastic foil are peeled from the finished device during the manufacturing process, which can lead to contamination of the front facet of the laser diode. If such contamination occurs, the laser diode may need to be scraped to remove the plastic. In general, the application of the adhesive, plastic removal, and scraping can be a labor intensive process that is difficult to automate.

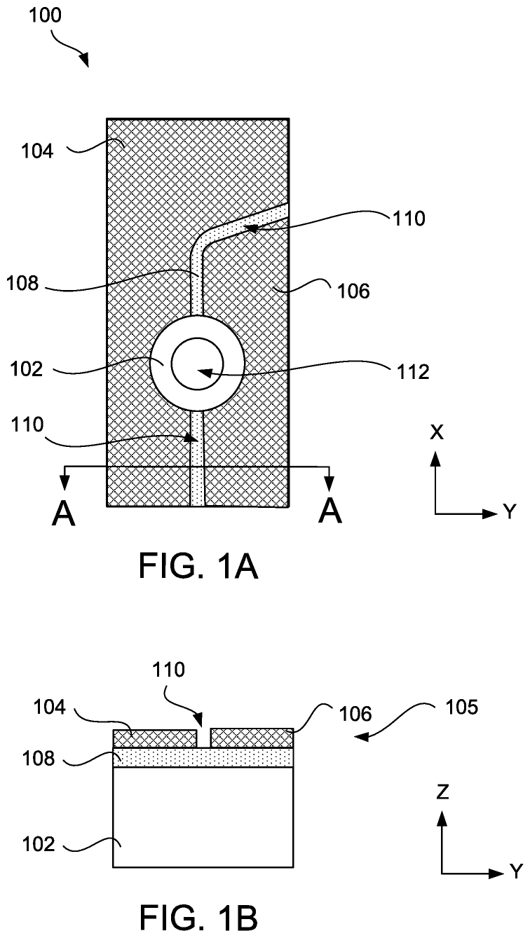

FIGS. 1A-1B are schematics illustrating an example of an electrically insulated laser diode cooler 100 that may be used in place of diode coolers that include the adhesive plastic foil. In particular, FIG. 1A is a schematic illustrating a top view of the electrically insulated cooler 100, whereas FIG. 1B is a side view of the electrically insulated cooler through section A-A of FIG. 1A.

The cooler 100 includes a heat sink that is formed from a main body portion 102 and an electrically insulating layer 108 on the main body portion 102. The main body portion 102 may include, for example, an internal coolant passage through which a coolant may flow to absorb heat generated by a laser diode and transfer the heat away to maintain the laser diode at a constant temperature. Accordingly, to provide for high heat transfer, both the main body portion 102 and layer 108 are formed from materials with high thermal conductivity. To reduce electro-corrosion with the main body portion 102, however, the material of layer 108 also may have high electrically insulating properties. For example, the main body portion may be formed from a metal, such as copper, which has a thermal conductivity of about 385.0 W/m*K, whereas the electrically insulating layer 108 may be formed from aluminum nitride, which has a thermal conductivity of about 140 W/m*K and an electrical resistivity of greater than about 10¹⁴ ohm*cm. In some cases, the cooler 100 also includes an opening 112 in the electrically insulating layer 108 and the main body portion 102. The opening 112 provides a coupling region into which the coolant may be provided.

A mounting layer 105 is formed on the electrically insulating layer 108. The mounting layer 105 is formed from a material with high electrical conductivity (e.g., a metal or composite such as copper, copper-diamond composite, molybdenum, silver or gold, among others) to provide electrical contact pads for the semiconductor laser diode. In contrast to laser diode coolers that employ plastic adhesive foils, the mounting layer 105 includes multiple electrical contact mounting pads that are electrically isolated from one another. For example, the mounting layer 105 may include a first mounting pad 104 and a second mounting pad 106. To electrically isolate the mounting pads from one another, the mounting pads may be separated by a physical gap. For example, as shown in FIGS. 1A and 1B, the first mounting pad 104 is physically and electrically separated from second mounting pad 106 by a gap 110. Because the mounting pads 104, 106 are also formed on electrically insulating layer 108, there is also little to no electrical conduction between the pads through layer 108. By electrically isolating the mounting pads from one another, the adhesive plastic foil that is used for bonding an electrical contact bar can be eliminated from the packaging design, since the foil is no longer necessary for providing electrical insulation.

The multiple contact pads (e.g., pads 104, 106) may be formed by first providing a layer of electrically conductive material (e.g., copper) onto an upper surface of the electrically insulating layer 108. For example, a layer of copper may be deposited directly onto the upper surface of electrically insulating layer 108. Standard deposition techniques such as physical vapor deposition, e-beam deposition, or electroplating, among others may be used to form the electrically conductive mounting layer 105. The electrically conductive material may be formed to have a thickness in the range of between about 50 nm and about several tens of microns including, e.g., between about 0.5 to about 15 microns.

The contact pads then may be defined by forming the gap in the as-provided electrically conductive material. For instance, the gap 110 may be formed by performing ion-milling or chemical etching of the electrically conductive material of the mounting layer 105 in just the region where gap 110 is to be defined. This process may include, e.g., depositing a resist as a mask, and then defining the gap region in the resist mask using lithography before performing the mill or etch. Other suitable techniques for defining the gap may be used instead. For example, in some cases, the gap 110 may be formed by stamping electrically conductive mounting layer 105 before bonding or mounting it to the electrically insulating layer 108. As a result of the etching process, multiple electrically isolated mounting pads, each having the same thickness may be formed directly in contact with the surface of the electrically insulating layer 108. In some implementations, forming the gap 110 may expose the underlying electrical insulating layer 108. A width of the gap 110 between facing edges of the first mounting pad 104 and the second mounting pad 106 may be less than about 1.5 mm. For example, the width of the gap 110 may be about 1.25 mm or less, 1 mm or less, 0.75 mm or less, or 0.5 mm or less.

In some implementations, the gap 110 between the mounting pads is empty (e.g., only air exists in the gap between each mounting pad). In other implementations, the gap 110 may be filled with an electrically insulating material. For instance, the gap 110 may be filled with a dielectric, polymer, epoxy or glue such as, e.g., Loctite® EA 3422. The gap material may be applied using, e.g., a syringe to fill the gap 110.

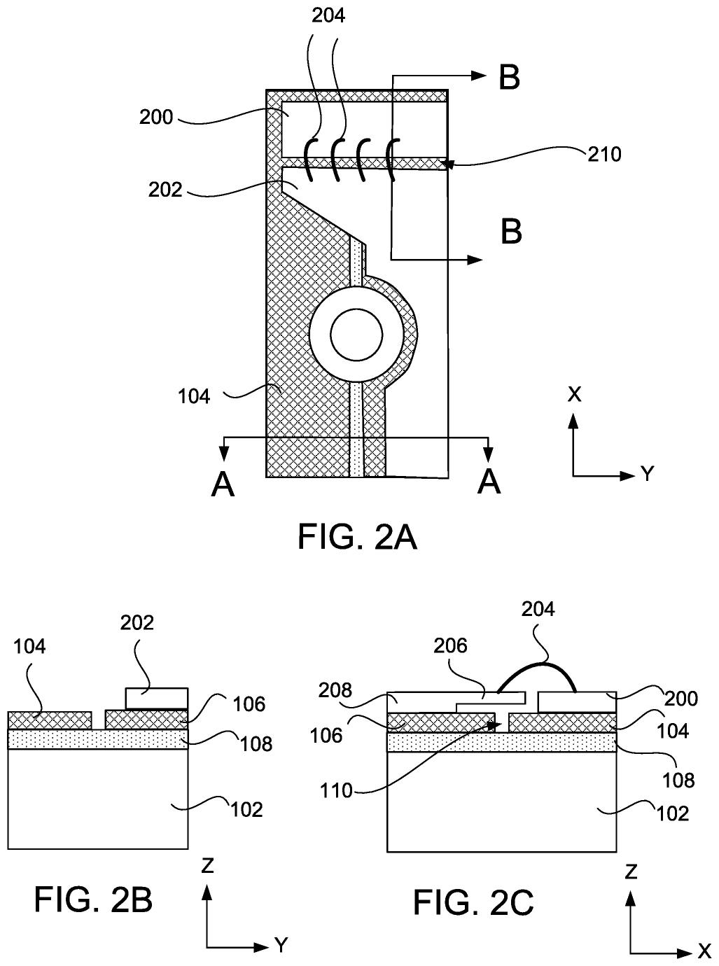

FIGS. 2A-2C are schematics that illustrate an example of a laser diode cooler, such as cooler 100, after a laser diode and contact bar are mounted to the mounting pads. In particular, FIG. 2A is a schematic that illustrates a top view of the laser diode cooler, whereas FIG. 2B is a schematic that illustrates a first side view of the cooler through section A-A of FIG. 2A and FIG. 2C is a schematic that illustrates a second side view of the cooler through section B-B.

In the example of FIGS. 2A-2C, laser diode 200 is mounted to the first mounting pad 104. For example, laser diode 200 may include a first electrode (e.g., a p-type contact) on its bottom surface that is electrically connected to the first mounting pad 104. The laser diode 200 can include, but is not limited to, edge emitting diodes such as, e.g., GaAs edge emitting laser diodes. The laser diode 200 may be physically and electrically connected to the first mounting pad 104 using a solder connection, e.g., a first solder layer between the mounting pad 104 and the laser diode 200. For example, the laser diode 200 may be soldered to first mounting pad 104 using a AuSn, AuSnBi, tin-silver-copper, silver sinter paste, gold diffusion bond, or other solder layer.

Separately, a contact bar 202 is mounted to the second mounting pad 106. The contact bar 202 provides an electrical contact region to which a second electrode (e.g., n-type contact) of the top surface of the laser diode 200 may be electrically connected. The contact bar 202 may include a material with high electrical conductivity, such as copper, copper-diamond composite, molybdenum, silver or gold, among others. The contact bar 202 may be physically and electrically connected to the second mounting pad 106 using a solder connection, e.g., a second solder layer between the mounting pad 106 and the contact bar 202. For example, the contact bar 202 may be soldered to the second mounting pad 106 using a AuSn solder layer. Because a solder layer is used in placed of a plastic adhesive foil, the problem of adhesive foil accidentally contaminating a facet of the laser diode 200 may be avoided. In some implementations, both the laser diode 200 and the contact bar 202 may be mounted during the same step in the packaging process, thus reducing the number of processing steps. For example, instead of mounting the laser diode 200 to an underlying mounting pad in a first step, and mounting the contact bar 202 using a plastic adhesive foil in a second separate step, both the contact bar 202 and the laser diode 200 may be mounted to their respective mounting pads at the same time using the same solder reflow process. The reduction in steps may offer increased time savings and potentially allows for automation of the packaging process.

After mounting both the laser diode 200 and the contact bar 202, an electrical connection is made between the top electrode (e.g., n-type contact) of the laser diode and the contact bar 202. For instance, the top contact of the laser diode 200 may be wire bonded to the contact bar 202 using wire bonds 204. In general, the distance of a gap 210 between an edge of the contact bar 202 that faces the laser diode 200 and an edge of the laser diode 200 that faces the contact bar 202 is between about 0.5 to about 1 mm. Each wire bond 204 may have a length (extending from the laser diode to the contact bar) of between about 5 mm and about 6 mm.

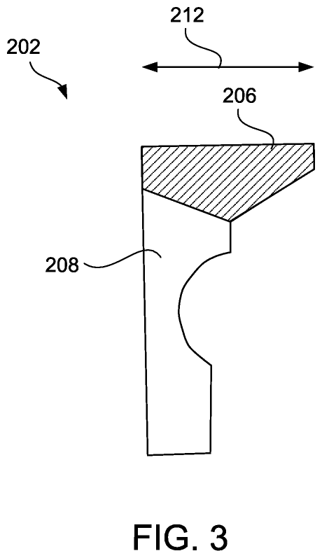

In some implementations, the contact bar 202 includes a shelf or ledge 206. The shelf or ledge 206 may be a region of the contact bar 202 where the bottom surface (i.e., the surface facing the underling mounting layer, e.g., mounting layer 105) is not in contact with the mounting layer 105. For example, as shown in FIG. 2C and 3, the shelf or ledge 206 of the contact bar 202 includes a region of contact bar that is thinner relative to a thickness of the portion 208 of contact bar that is soldered to the second mounting pad 106. By forming the ledge or shelf region 206 in the manner as shown in FIG. 2C, the contact bar 202 does not come into physical contact with the first mounting pad 104. Thus, the shelf 206 helps maintain electrical isolation of the contact bar 202 from first mounting pad 104. As also shown in FIG. 2C, the shelf or ledge region 206 extends over an edge of the second mounting pad 106 and over gap 110. Extending the shelf or ledge region 206 over the gap 110 allows the contact bar to be positioned closer to the laser diode 200 so that the wire bonds 204 may be easily formed, without requiring bond lengths that are too long. The shelf or ledge region 206 may extend beyond the edge of the second mounting pad 106 in a direction toward the laser diode 200 by less than about 2 mm. For example, the shelf or ledge region 206 may extend beyond the edge of the second mounting pad 106 by about 1.5 mm or less, about 1.25 mm or less, about 1 mm or less, about 0.75 mm or less, about 0.5 mm or less, or by about 0.25 mm or less. Accordingly, in some implementations, the shelf or edge region 206 extends entirely over the gap 110 between the first and second mounting pads 104, 106 and, in some cases, also extends over a portion of the first mounting pad 104.

FIG. 3 is a schematic that illustrates a bottom view of the contact bar 202. The bottom view depicts the surface of the contact bar 202 that faces the underlying mounting layer 105. As explained herein, the shelf or ledge region 206 of the contact bar 202 may correspond to a region of the contact bar 202 that is thinner than a region of the contact bar 202 that is directly mounted on the underlying mounting pad. The shelf or ledge region 206 may be formed by removing a portion of the contact bar. For example, the shelf or ledge region 206 may be formed by milling or etching the contact bar 202. The remaining portion 208 of the contact bar 202 that is not removed may then be bonded to the underlying mounting pad (e.g., second mounting pad 106) using a solder layer. The edge of the shelf or ledge region 206 that faces the laser diode 200 may have a width 212. The width 212 may be substantially the same as a width of the laser diode edge that the shelf 206 faces to allow wire bonds to be formed across the width of the laser diode. For instance, the width 212 can range, in some implementations, from about 1 mm to about 20 mm.

In some implementations, an electrically insulating material may be formed in the space between the shelf or ledge region 206 of the contact bar 202 and the upper facing surface of the mounting layer 105. The electrically insulating material may include a dielectric, polymer, epoxy or glue such as, e.g., Loctite® EA 3422. The gap material may be applied using, e.g., a syringe to fill the gap 110. The gap material may be applied using, e.g., a syringe to fill the gap 110. The electrically insulating material that fills the space between shelf or ledge 206 and the mounting layer 105 may provide additional bonding force to hold the contact bar 202 in place. In some implementations, the electrically insulating material may ensure that the shelf region 206 does not come into electrical contact with the first mounting pad 104.

Other aspects, advantages, and modifications are within the scope of the following claims.

What is claimed is:

1. A laser diode device comprising:
a heat sink comprising a main body portion and an electrical insulating layer on the main body portion;
a mounting layer on the electrical insulating layer, wherein the mounting layer comprises a first mounting pad and a second mounting pad electrically isolated from one another;
a laser diode bar on the first mounting pad;
a contact bar on the second mounting pad;
a first solder layer providing an electrical connection between the contact bar and the second mounting pad; and
a plurality of wire bonds providing an electrical connection from a top surface of the laser diode bar to a top surface of the contact bar.

2. The laser diode device of claim 1, wherein the first mounting pad is separated from the second mounting pad by a gap.

3. The laser diode device of claim 2, wherein a width of the gap between facing edges of the first mounting pad and the second mounting pad is less than about 1.5 mm.

4. The laser diode device of claim 2, wherein an edge of the contact bar extends over an edge of the second mounting pad and overlaps the gap.

5. The laser diode device of claim 4, wherein the edge of the contact bar extends over the edge of the second mounting pad by less than about 0.5 mm.

6. The laser diode device of claim 2, wherein an edge of the contact bar extends entirely over the gap.

7. The laser diode device of claim 2, wherein an edge of the contact bar extends over the gap and over a portion of the first mounting pad.

8. The laser diode device of claim 2, wherein a dielectric material fills the gap.

9. The laser diode device of claim 8, wherein the dielectric material comprises an epoxy.

10. The laser diode device of claim 2, wherein a distance between facing edges of the contact bar and the laser diode bar is between approximately 0.5 mm to approximately 1 mm.

11. The laser diode device of claim 2, comprising a second solder layer between the first mounting pad and a bottom surface of the laser diode bar, wherein the second solder layer provides an electrical connection between a first electrode on the bottom surface of the laser diode bar and the first mounting pad.

12. The laser diode device of claim 10, wherein the top surface of the laser diode bar comprises a second electrode, and the plurality of wire bonds provide an electrical connection from the second electrode to the contact bar.

13. The laser diode device of claim 2, wherein each wire bond of the plurality of wire bonds has a length of between approximately 5 mm and approximately 6 mm.

14. A method of manufacturing a laser diode device, the method comprising:
providing a heat sink, wherein the heat sink comprises a main body portion, an electrical insulating layer on the main body portion, and a mounting layer on the electrical insulating layer;
modifying the mounting layer to form a first mounting pad and a second mounting pad electrically isolated from the first mounting pad;
mounting a laser diode bar on the first mounting pad so that the laser diode is electrically connected to the first mounting pad;
mounting a contact bar on the second mounting pad;
electrically connecting the laser diode bar to the contact bar by providing a plurality of wire bonds that couple to a top surface of the laser diode bar and to a top surface of the contact bar.

15. The method of manufacturing a laser diode device of claim 14, wherein modifying the mounting layer to form the first mounting pad and the second mounting pad comprises stamping the mounting layer to form a gap within the mounting layer wherein the gap defines a separation between the first mounting pad and the second mounting pad.

16. The method of manufacturing a laser diode device of claim 14, wherein modifying the mounting layer to form the first mounting pad and the second mounting pad comprises milling or etching the mounting layer to form a gap within the mounting layer wherein the gap defines a separation between the first mounting pad and the second mounting pad.

17. The method of manufacturing a laser diode device of claim 14 wherein modifying the mounting layer to form the first mounting pad and the second mounting pad comprises forming a gap within the mounting layer, wherein the gap defines a separation between the first mounting pad and the second mounting pad, and
wherein mounting the contact bar comprises positioning the contact bar on the second mounting pad such that an edge of the contact bar extends over the gap.

18. The method of manufacturing a laser diode device of claim 17, comprising filling the gap with a dielectric material.

19. The method of manufacturing a laser diode device of claim 14, wherein mounting the contact bar on the second mounting pad comprises soldering the contact bar to the second mounting pad to electrically connect the contact bar to the second mounting pad.

20. The method of manufacturing a laser diode device of claim 14, comprising soldering the contact bar to the second mounting pad and soldering the laser diode bar to the first mounting pad at the same time.
